(19) United States
(12) Patent Application Publication
(10) Pub. No.: US 2026/0047258 A1
(43) Pub. Date: Feb. 12, 2026

(54) MICRO LED DISPLAY CHIP AND METHOD FOR FORMING THE SAME

(71) Applicant: JADE BIRD DISPLAY ( SHANGHAI) LIMITED, Shanghai (CN)

(72) Inventors: Feng FENG, Shanghai (CN); Hao Wang, Shanghai (CN); Jian Guo, Shanghai (CN)

(73) Assignee: JADE BIRD DISPLAY ( SHANGHAI) LIMITED, Shanghai (CN)

(21) Appl. No.: 19/294,309

(22) Filed: Aug. 8, 2025

(30) Foreign Application Priority Data
Aug. 8, 2024 (CN) 202411091976.4

(51) Int. Cl. H10H 29/80; H10H 20/812; H10H 29/01; H10H 29/14

(52) U.S. Cl. CPC H10H 29/8421; H10H 29/012; H10H 29/034; H10H 29/142; H10H 20/812

(57) ABSTRACT

A Micro LED display chip and a method for forming the same are provided. The method includes: forming a base including light emitting mesas arranged in an array; forming a passivation layer on a sidewall surface of each light emitting mesa and a surface of the base, and the passivation layer exposes a top surface of each light emitting mesa; and forming a light reflection layer on the top surface of each light emitting mesa and on a part or whole of the passivation layer on the sidewall surface of each light emitting mesa. A light reflectivity of a material of the light reflection layer is greater than or equal to a preset light reflectivity threshold, which can improve a light emission rate and a brightness of the Micro LED display chip.

### CROSS-REFERENCE TO RELATED APPLICATIONS

This application claims the benefit of priority to Chinese patent application No. 202411091976.4, filed on Aug. 8, 2024, entitled “MICRO LED DISPLAY CHIP AND METHOD FOR FORMING THE SAME”, the entire disclosures of which are incorporated herein by reference.

### FIELD

The present disclosure relates to the field of semiconductor manufacturing, and more particularly to a Micro LED display chip and a method for forming the same.

### BACKGROUND

Micro Light Emitting Diode (LED) devices, as small-sized (such as less than 50 μm) and luminescent semiconductor components, have advantages of low power consumption, long lifespan, high brightness and high contrast. With gradual development of display technology, light emitting mesa technology has gradually become a trend in new display technology and is receiving increasing attention.

However, current light emitting mesas often have low light emission and brightness, making it difficult to meet demands.

### SUMMARY OF THE DISCLOSURE

Embodiments of the present disclosure provide a Micro LED display chip and a method for forming the Micro LED display chip, which can improve a light emission rate and a brightness of the Micro LED display chip.

According to an embodiment of the present disclosure, a method for forming a Micro LED display chip is provided. The method includes: forming a base including light emitting mesas arranged in an array; forming a passivation layer on a sidewall surface of each of the light emitting mesas and a surface of the base, and the passivation layer exposes a top surface of each of the light emitting mesas; and forming a light reflection layer on the top surface of each of the light emitting mesas and on a part or whole of the passivation layer on the sidewall surface of each of the light emitting mesas; and a light reflectivity of a material of the light reflection layer is greater than or equal to a preset light reflectivity threshold.

According to some embodiments, the material of the light reflection layer includes a stacked layer including one or more of a silver layer, an aluminum layer and a gold layer.

According to some embodiments, the preset light reflectivity threshold is greater than or equal to 85%.

According to some embodiments, a light transmittance of the light reflection layer is less than a preset light transmittance threshold.

According to some embodiments, the preset light transmittance threshold is less than or equal to 10%.

According to some embodiments, the method further includes: forming a protective layer on the base, and the protective layer covers at least the light reflection layer.

According to some embodiments, the protective layer is formed by an ALD process.

According to some embodiments, the protective layer includes a stacked layer including one or more of a silicon nitride layer, a titanium oxide layer and an aluminum oxide layer.

According to some embodiments, the protective layer satisfies one or more of the following: the protective layer is a silicon nitride layer, and a thickness of the silicon nitride layer is in a range from 300 nm to 500 nm; the protective layer is a titanium oxide layer, and a thickness of the titanium oxide layer is in a range from 30 nm to 80 nm; and the protective layer is an aluminum oxide layer, and a thickness of the aluminum oxide layer is in a range from 30 nm to 80 nm.

According to some embodiments, the protective layer covers the light reflection layer and the base.

According to some embodiments, forming the base includes: forming a substrate having a light emitting mesa region; forming a first confinement layer, a quantum well layer and a second confinement layer on the substrate; forming a patterned first photoresist layer, and the first photoresist layer covers each light emitting mesa in the light emitting mesa region and exposes an area between adjacent light emitting mesas; etching the second confinement layer using the first photoresist layer and then removing the first photoresist layer; forming a patterned second photoresist layer, and a coverage size of the second photoresist layer covering each light emitting mesa is greater than a coverage size of the first photoresist layer covering each light emitting mesa, and the second photoresist layer covers the second confinement layer of each light emitting mesa and a part of a surface of the quantum well layer surrounding the second confinement layer; and etching the quantum well layer and the first confinement layer using the patterned second photoresist layer to form a stepped light emitting mesa.

According to some embodiments, the method further includes: etching the second confinement layering with an inward inclined etching angle greater than 0 degrees to obtain a sloped second confinement layer; and/or etching the quantum well layer and the first confinement layer with an inward inclined angle greater than 0 degrees to obtain a sloped quantum well layer and a sloped first confinement layer; and the inward inclined etching angle refers to an etching direction from diagonally above to diagonally below and from a position near a center of each light emitting mesa to a position away from the center of each light emitting mesa.

According to some embodiments, a light transmittance of a material of the passivation layer is greater than or equal to a preset light transmittance threshold.

According to some embodiments, the preset light transmittance threshold is greater than or equal to 90%.

According to some embodiments, the passivation layer includes a stacked layer including one or more of a silicon oxide layer, an aluminum oxide layer, a silicon nitride layer and a polyimide layer.

According to some embodiments, the method further includes: forming a first bonding layer on the base and forming a first conductive connector in the first bonding layer; forming a driving backplane, forming a second bonding layer on the driving backplane, and forming a second conductive connector in the second bonding layer, and a position of the second conductive connector corresponds to a position of the first conductive connector; and connecting the driving backplane and the base through flip-chip bonding to electrically connect the first conductive connector and the second conductive connector.

According to some embodiments, the method further includes: removing a buffer layer from a second surface of the base to expose a back surface of each of the light emitting mesas, and etching a first electrode region to obtain a groove or a hole for forming a first electrode; forming a second electrode on the second surface of the base and forming the first electrode electrically connected with the second conductive connector.

According to some embodiments, the second electrode surrounds each of the light emitting mesas and exposes the back surface of each of the light emitting mesas.

According to some embodiments, the method further includes: forming a micro lens on each of the light emitting mesas.

According to another embodiment of the present disclosure, a Micro LED display chip is provided. The Micro LED display chip includes: a base including a light emitting mesas arranged in an array; a passivation layer on a sidewall surface of each of the light emitting mesas and a surface of the base, and the passivation layer exposes a top surface of each of the light emitting mesas; and a light reflection layer on the top surface of each of the light emitting mesas and on a part or whole of the passivation layer on the sidewall surface of each of the light emitting mesas; and a light reflectivity of a material of the light reflection layer is greater than or equal to a preset light reflectivity threshold.

According to some embodiments, the material of the light reflection layer includes a stacked layer including one or more of a silver layer, an aluminum layer and a gold layer.

According to some embodiments, the preset light reflectivity threshold is greater than or equal to 85%.

According to some embodiments, a light transmittance of the light reflection layer is less than a preset light transmittance threshold.

According to some embodiments, the preset light transmittance threshold is less than or equal to 10%.

According to some embodiments, the Micro LED display chip further includes: a protective layer on the base, and the protective layer covers at least the light reflection layer.

According to some embodiments, the protective layer includes a stacked layer including one or more of a silicon nitride layer, a titanium oxide layer and an aluminum oxide layer.

According to some embodiments, the protective layer satisfies one or more of the following: the protective layer is a silicon nitride layer, and a thickness of the silicon nitride layer is in a range from 300 nm to 500 nm; the protective layer is a titanium oxide layer, and a thickness of the titanium oxide layer is in a range from 30 nm to 80 nm; and the protective layer is an aluminum oxide layer, and a thickness of the aluminum oxide layer is in a range from 30 nm to 80 nm.

According to some embodiments, the protective layer covers the light reflection layer and the base.

According to some embodiments, the base includes: a substrate having a light emitting mesa region; and a stepped light emitting mesa including a first confinement layer, a quantum well layer and a second confinement layer on the substrate; and a width of the first confinement layer is greater than a width of the second confinement layer.

According to some embodiments, the stepped light emitting mesa is formed by etching the first confinement layer, the quantum well layer and the second confinement layer using a patterned first photoresist layer and a patterned second photoresist layer respectively; and and a coverage size of the second photoresist layer covering each light emitting mesa is greater than a coverage size of the first photoresist layer covering each light emitting mesa.

According to some embodiments, the second confinement layer is a sloped second confinement layer; and/or the first confinement layer is a sloped first confinement layer, and the quantum well layer is a sloped quantum well layer.

According to some embodiments, the sloped second confinement layer is formed by etching the second confinement layer with an inward inclined etching angle greater than 0 degrees; and/or the sloped quantum well layer and the sloped first confinement layer are formed by etching the quantum well layer and the first confinement layer with an inward inclined etching angle greater than 0 degrees; and the inward inclined etching angle refers to an etching direction from diagonally above to diagonally below and from a position near a center of each light emitting mesa to a position away from the center of each light emitting mesa.

Compared with conventional technology, the embodiments of the present disclosure have following advantages.

In some embodiments of the present disclosure, by forming the passivation layer on the light emitting mesas and forming the light reflection layer on a part or whole of the passivation layer on the sidewall surface of the light emitting mesas, light emitted by the light emitting mesas can be effectively reflected, and a portion of the light emitted by the light emitting mesas that is not included in a preset light emission angle (such as within plus or minus) 20° can change direction of light path after being reflected by the light reflection layer, becoming within the preset light emission angle, which can effectively improve a light emission rate and a brightness of the Micro LED display chip.

Furthermore, the light transmittance of the light reflection layer is less than the preset light transmittance threshold, which can reduce the light passing through the light reflection layer and allow more light to be reflected back within the preset light emission angle (such as within plus or minus 20°), and further improve the light emission rate and the brightness of the Micro LED display chip.

Furthermore, the protective layer is formed on the base, and the protective layer covers at least the light reflection layer. The light reflection layer made of more active metal materials may cause issues such as electromigration and metal material diffusion. By forming the protective layer covering at least the light reflection layer, the electromigration and the metal material diffusion can be effectively controlled, which can improve lifespan and light emission efficiency of the Micro LED display chip.

Furthermore, by providing the protective layer to cover the light reflection layer and the base, the protective layer can be positioned on a carrier path between the first electrode and the second electrode for isolation, which can further reduce a leakage current between the first electrode and the second electrode, and improve an electrical performance of the Micro LED display chip.

Furthermore, the protective layer is formed by an ALD process, and a higher density protective layer can be formed with the same material, which can further enhance a prevention effect on the electromigration and the metal material diffusion.

Furthermore, the protective layer may be formed of a silicon nitride layer, a titanium oxide layer or an aluminum oxide layer, and an appropriate thickness can be selected to achieve a better balance between process cost and device performance.

Furthermore, by using two patterned photoresist layers, the coverage size of the second photoresist layer on each light emitting mesa is greater than the coverage size of the first photoresist layer on each light emitting mesa, thus the stepped light emitting mesa with a narrower second confinement layer, a wider quantum well layer and a wider first confinement layer can be formed. Therefore, based on a preset design size of the light emitting mesas, an actual size of the quantum well layer can be increased as much as possible. As the quantum well layer is used for light emission, the light emission can be effectively increased, which can further improve the brightness of the Micro LED display chip.

Furthermore, the sloped second confinement layer is formed by etching the second confinement layer with an inward inclined etching angle greater than 0 degrees; and/or the sloped quantum well layer and the sloped first confinement layer are formed by etching the quantum well layer and the first confinement layer with an inward inclined etching angle greater than 0 degrees. Thus, a sloped and stepped light emitting mesa is formed on the basis of the stepped light emitting mesa, which can improve a continuity of a sloped sidewall of the light emitting mesas. Moreover, a size of the second confinement layer is as close as possible to a size of the quantum well layer on a contact surface, which helps to maintain other electrical properties of the light emitting mesas while increasing the actual size of the quantum well layer.

### BRIEF DESCRIPTION OF THE DRAWINGS

FIG. 1 is a flowchart of a method for forming a Micro LED display chip according to an embodiment of the present disclosure;

FIG. 2 is a top view of an intermediate structure of a Micro LED display chip according to an embodiment of the present disclosure; and

FIGS. 3 to 13 are schematic structural sectional views of devices corresponding to each step in a method for forming a Micro LED display chip according to an embodiment of the present disclosure.

### DETAILED DESCRIPTION

As mentioned above, the light emitting mesa technology is receiving increasing attention. However, current light emitting mesa devices often have low light emission and brightness, making it difficult to meet demands.

In an existing Micro LED display chip, if light emitted by a light emitting mesa is not included in a preset light emission angle (such as within plus or minus 20°), the light may escape from an opposite direction of a light emission surface after being reflected by air or a structural component, which may cause serious light leakage and affect a light emission rate and a brightness of the Micro LED display chip.

In some embodiments of the present disclosure, by forming a passivation layer on light emitting mesas and forming a light reflection layer on a part or whole of the passivation layer on a sidewall surface of the light emitting mesas, light emitted by the light emitting mesas can be effectively reflected, and a portion of the light emitted by the light emitting mesas that is not included in a preset light emission angle (such as within plus or minus 20°) can change direction of light path after being reflected by the light reflection layer, becoming within the preset light emission angle, which can effectively improve the light emission rate and the brightness of the Micro LED display chip.

In order to make above objectives, features and advantages of the present disclosure more obvious and understandable, specific embodiments of the present disclosure will be clearly and completely described below in conjunction with the accompanying drawings.

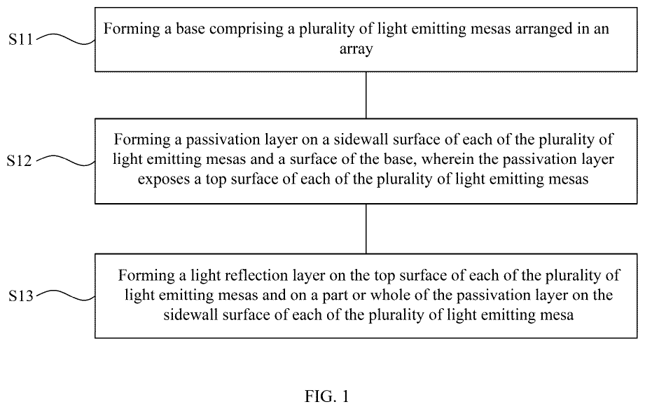

FIG. 1 is a flowchart of a method for forming a Micro LED display chip according to an embodiment of the present disclosure. Referring to FIG. 1, the method for forming the Micro LED display chip may include following steps.

S11: forming a base, where the base includes a light emitting mesas arranged in an array.

S12: forming a passivation layer on a sidewall surface of each of the light emitting mesas and a surface of the base, where the passivation layer exposes a top surface of each of the light emitting mesas.

S13: forming a light reflection layer on the top surface of each of the light emitting mesas and on a part or whole of the passivation layer on the sidewall surface of each of the light emitting mesas.

A light reflectivity of a material of the light reflection layer is greater than or equal to a preset light reflectivity threshold.

The above steps will be explained in conjunction with the accompanying drawings.

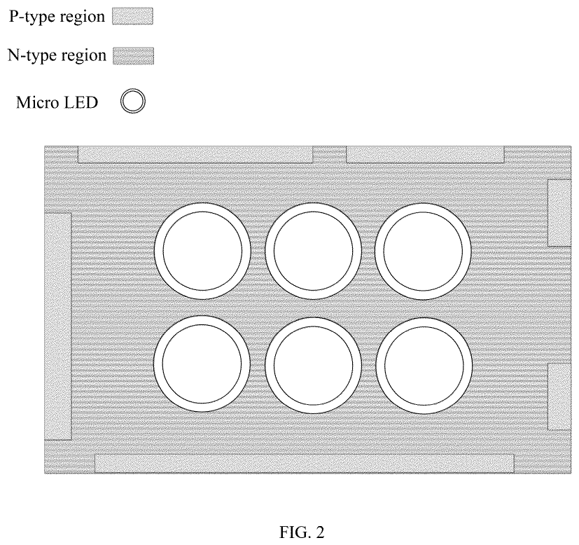

FIG. 2 is a top view of an intermediate structure of a Micro LED display chip according to an embodiment of the present disclosure.

Referring to FIG. 2, the Micro LED display chip may include a base. The base may include a light emitting mesa, an N-type electrode region and a P-type electrode region.

The N-type electrode region may include a pixel region and an electrode region, and the base in the pixel region includes a light emitting mesas distributed in an array.

The electrode region of the N-type electrode region may be used to form an N-type electrode, and the P-type electrode region may be used to form a P-type electrode.

In the Micro LED display chip shown in FIG. 2, the P-type electrode region can partially surround the N-type electrode region.

It should be noted that the Micro LED display chip in specific applications may not be limited by the top view of the Micro LED display chip shown in FIG. 2. For example, the size, quantity and position of the P-type electrode region may be adjusted according to specific situations.

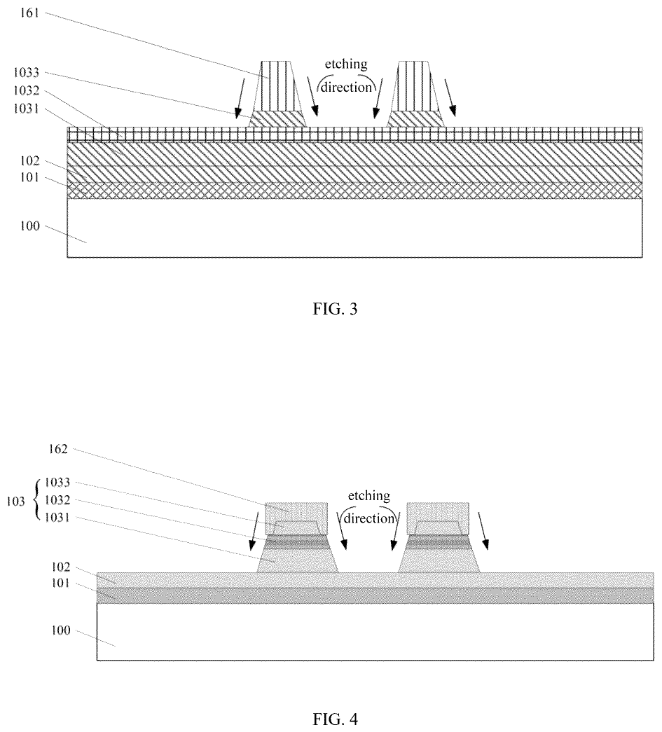

FIGS. 3 to 13 are schematic structural sectional views of devices corresponding to each step in a method for forming a Micro LED display chip according to an embodiment of the present disclosure.

Referring to FIG. 3, a portion of the base is formed.

Specifically, a substrate 100 is provided. A buffer layer 101 is formed on the substrate 100, and a material layer of an epitaxial layer 102 is formed on the buffer layer 101.

In some embodiments, the substrate 100 may include a sapphire substrate, and the substrate 100 may include aluminum oxide (Al₂O₃).

In other embodiments, the substrate 100 may include a substrate of other suitable material, for example, a semiconductor substrate, such as a silicon substrate. The material of the semiconductor substrate may also include germanium, silicon germanium, silicon carbide, gallium arsenide or indium gallium. The semiconductor substrate may also be a silicon substrate on an insulator or a germanium substrate on an insulator, or a substrate grown with an epitaxial layer (Epi layer).

In some embodiments, the epitaxial layer 102 may include one or more of the following: a first confinement layer 1031, a quantum well layer 1032 and a second confinement layer 1033.

The first confinement layer 1031 may be an N-type group III-V compound layer, and correspondingly, the second confinement layer 1033 may be a P-type group III-V compound layer.

The quantum well layer 1032 may be a material layer suitable for forming a quantum well structure, such as a group III-V compound layer.

It should be noted that the group III-V compound layer represents a material layer formed by compounds of a group III element and a group V element. The group III element may include B, Al, Ga and In, and the group V element may include N, P, As and Sb.

In some embodiments, the group III-V compound layer may be selected according to actual requirements, and the specific group III-V compound in the first confinement layer 1031, the quantum well layer 1032 and second confinement layer 1033 may be consistent or inconsistent.

In a specific implementation, the group III-V compound layer may be selected from GaN, GaAs and InP.

It should be noted that the epitaxial layer 102 may also include other appropriate layers, such as sacrificial layers. The specific structure of the epitaxial layer 102 is not limited by the embodiments of the present disclosure.

In some embodiments, a material layer of a transparent conductive layer 104 may also be formed on the material layer of the epitaxial layer 102, and then the transparent conductive layer 104 may be etched together when etching the second confinement layer 1033.

In some embodiments, the material of the transparent conductive layer 104 may include indium tin oxide (In₂O₅Sn), which can improve conductivity and light emission effect and reduce Ohmic effect.

It should be noted that the material of the transparent conductive layer 104 may also include other suitable materials, such as fluorine doped tin oxide (FTO) and zinc oxide (ZnO).

It should be noted that in some embodiments, after etching the first confinement layer 1031, the quantum well layer 1032 and the second confinement layer 1033 to obtain each light emitting mesa 103, the transparent conductive layer 104 may be formed on the top surface of each light emitting mesa 103. Therefore, in order to illustrate the process of forming each light emitting mesa 103 more clearly, the transparent conductive layer 104 is not shown in FIGS. 3 to 4. However, this does not constitute a limitation on specific steps and processes of forming the transparent conductive layer 104.

In the embodiment shown in FIG. 3, a patterned first photoresist layer 161 may also be formed. The patterned first photoresist layer 161 covers each light emitting mesa in the light emitting mesa region and exposes an area between adjacent light emitting mesas.

Then, by etching the second confinement layer 1033 using the first photoresist layer 161, the second confinement layer 1033 except for each light emitting mesa may be removed to retain the second confinement layer 1033 of each light emitting mesa and expose a surface of the quantum well layer 1032 except for each light emitting mesa.

Furthermore, an inward inclined etching angle greater than 0 degrees may be used to etch the second confinement layer 1033 to obtain a sloped second confinement layer 1033.

In an etching direction as shown in FIG. 3, the inward inclined etching angle is used to indicate the etching direction from diagonally above to diagonally below and from a position near a center of each light emitting mesa 103 to a position away from the center of each light emitting mesa 103.

In some embodiments, an etching angle inclined inward and greater than 0 may be formed through any appropriate methods.

In some embodiments, a sloped patterned photoresist layer (such as the first photoresist layer 161 shown in FIG. 3) can be formed to form a slope collapse morphology.

In other embodiments, a patterned photoresist layer with a conventional morphology may be formed (such as a second photoresist layer 162 shown in FIG. 4), and then etching process parameters may be adjusted to achieve a gradually narrowing etching morphology.

Referring to FIG. 4, the first photoresist layer 161 (see FIG. 3) is removed to form the patterned second photoresist layer 162. A coverage size of the second photoresist layer 162 on each light emitting mesa 103 is greater than a coverage size of the first photoresist layer 161 on each light emitting mesa 103, and the second photoresist layer 162 covers the second confinement layer 1033 of each light emitting mesa 103 and a portion of a surface of the quantum well layer 1032 surrounding the second confinement layer 1033. The patterned second photoresist layer 162 is used to etch the quantum well layer 1032 and the first confinement layer 1031 to form a stepped light emitting mesa 103.

In some embodiments, the coverage size can be represented by a coverage area, or by parameters such as a diameter, a radius or a diagonal length of the coverage area.

As shown in FIG. 4, due to a greater coverage size of the second photoresist layer 162, a stepped morphology is formed between the second confinement layer 1033 and the quantum well layer 1032.

In some embodiments, by using two patterned photoresist layers, the coverage size of the second photoresist layer 162 on each light emitting mesa 103 is greater than the coverage size of the first photoresist layer 161 on each light emitting mesa 103, thus the stepped light emitting mesa with a narrower second confinement layer 1033, a wider quantum well layer 1032 and a wider first confinement layer 1031 can be formed. Therefore, based on a preset design size of the light emitting mesa 103, an actual size of the quantum well layer 1032 can be increased as much as possible. As the quantum well layer 1032 is used for light emission, the light emission can be effectively increased, which can further improve the brightness of the Micro LED display chip.

Furthermore, an inward inclined etching angle greater than 0 degrees may be used to etch the quantum well layer 1032 and the first confinement layer 1031 to obtain a sloped quantum well layer 1032 and a sloped first confinement layer 1031.

In an etching direction as shown in FIG. 4, the inward inclined etching angle is used to indicate the etching direction from diagonally above to diagonally below and from a position near the center of each light emitting mesa 103 to a position away from the center of the light emitting mesa 103.

In some embodiments, an etching angle inclined inward and greater than 0 may be formed through any appropriate methods.

In some embodiments, a sloped patterned photoresist layer (such as the first photoresist layer 161 shown in FIG. 3) can be formed to form a slope collapse morphology.

In other embodiments, a patterned photoresist layer with a conventional morphology may be formed (such as the second photoresist layer 162 shown in FIG. 4), and then etching process parameters may be adjusted to achieve a gradually narrowing etching morphology.

In some embodiments, the second confinement layer 1033 is etched using an inward inclined etching angle greater than 0 degrees to obtain a sloped second confinement layer 1033; and/or, the quantum well layer 1032 and the first confinement layer 1031 are etched using an inward inclined etching angle greater than 0 degrees to obtain a sloped quantum well layer 1032 and a sloped first confinement layer 1031. Thus, a sloped and stepped light emitting mesa 103 is formed on the basis of the stepped light emitting mesa 103, which can improve a continuity of a sloped sidewall of the light emitting mesas 103. Moreover, a size of the second confinement layer 1033 is as close as possible to a size of the quantum well layer 1032 on a contact surface, which helps to maintain other electrical properties of the light emitting mesas 103 while increasing the actual size of the quantum well layer 1032.

It should be noted that during forming the light emitting mesas 103, a portion of the first confinement layer 1031 in the epitaxial layer 102 may be retained.

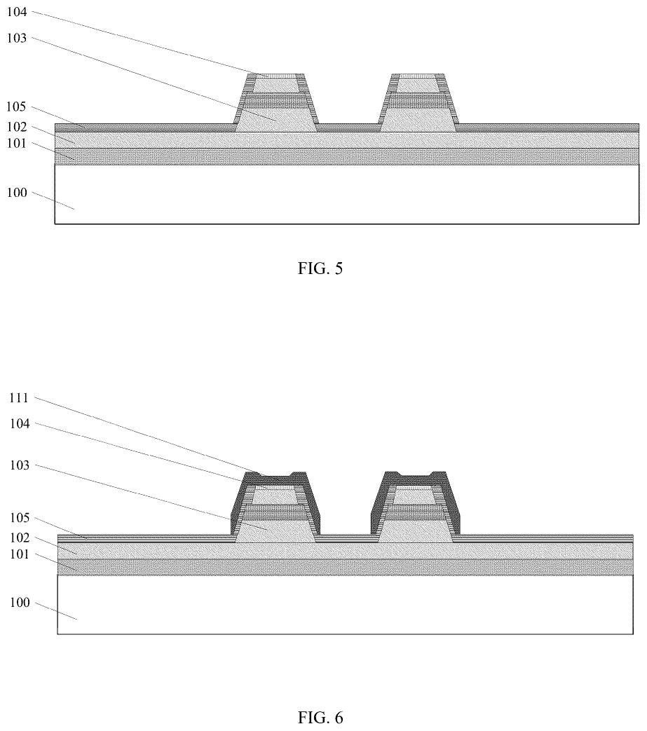

Referring to FIG. 5, the second photoresist layer 162 is removed to form a passivation layer 105.

As mentioned above, the transparent conductive layer 104 may also be formed.

Specifically, a material layer of the transparent conductive layer 104 may be formed on the material layer of the epitaxial layer 102, and then during etching the second confinement layer 1033, the material layer of the transparent conductive layer 104 may be etched together to obtain the transparent conductive layer 104. After etching the first confinement layer 1031, the quantum well layer 1032 and the second confinement layer 1033 to obtain the light emitting mesas 103, the transparent conductive layer 104 can be formed on the top surface of the light emitting mesas 103.

In some embodiments, the passivation layer 105 may be formed on the sidewall surface of each light emitting mesa 103 and the surface of the base, and expose the top surface of each light emitting mesa 103.

In some embodiments, the passivation layer 105 may also be formed to cover the base and expose the top surface of each light emitting mesa 103. In other words, the passivation layer 105 may cover the sidewall surface of each light emitting mesa 103.

In the process of forming the passivation layer 105, a passivation layer material covering the transparent conductive layer 104 may be first formed, and then the passivation layer material on the top surface of each light emitting mesa 103 may be removed.

The material of the passivation layer 105 may include a stacked layer including one or more of the following: a silicon oxide layer, an aluminum oxide layer, a silicon nitride layer and a polyimide layer.

Specifically, the passivation layer material may be removed through a photolithography process and an etching process, and other appropriate process steps may also be used. The embodiments of the present disclosure do not limit specific process implementation.

Furthermore, a light transmittance of the material of the passivation layer 105 may be greater than or equal to a preset light transmittance threshold.

In some embodiments, the preset light transmittance threshold may be greater than or equal to 90%.

In some embodiments, the preset light transmittance threshold may be in a range from 95% to 98%.

In some embodiments, by setting the light transmittance of the material of the passivation layer 105 to be greater than or equal to the preset light transmittance threshold, the light transmittance can be increased, and the absorption of light by the passivation layer 105 can be reduced, thus more light can pass through the passivation layer 105 on the sidewall of the light emitting mesas and be reflected by the light reflection layer, which can effectively control the optical path.

Referring to FIG. 6, a light reflection layer 111 is formed. The light reflection layer 111 is formed on the top surface of each light emitting mesa 103 and on a part or whole of the passivation layer 105 on the sidewall surface of each light emitting mesa 103.

In some embodiments, a light reflectivity of a material of the light reflection layer 111 may be greater than or equal to a preset light reflectivity threshold.

In some embodiments of the present disclosure, by forming the passivation layer 105 on the light emitting mesas 103 and forming the light reflection layer 111 on a part or whole of the passivation layer 105 on the sidewall surface of the light emitting mesas 103, the light emitted by the light emitting mesas 103 can be effectively reflected, and a portion of the light emitted by the light emitting mesas 103 that is not included in the preset light emission angle (such as within plus or minus 20°) can change direction of light path after being reflected by the light reflection layer 111, becoming within the preset light emission angle, which can effectively improve the light emission rate and the brightness of the Micro LED display chip.

In some embodiments, the material of the light reflection layer 111 may include a stacked layer including one or more of the following: a silver layer, an aluminum layer and a gold layer.

In some embodiments, by setting appropriate materials as the light reflection layer 111, such as using active metal materials such as silver, aluminum or gold, to form the light reflection layer 111, the light reflectivity can be improved, which can form the effect of a “reflection mirror”.

In some embodiments, the preset light reflectivity threshold may be greater than or equal to 85%.

In some embodiments, a silver layer is used as the light reflection layer 111, and the light reflectivity may be greater than 90%.

In another specific embodiment, a gold layer is used as the light reflection layer 111, and the light reflectivity may be in a range from 85% and 88%.

In another specific embodiment, an aluminum layer is used as the light reflection layer 111, and the light reflectivity may be greater than 90%.

In some embodiments of the present disclosure, by setting the light reflectivity of the material of the light reflection layer 111 to be greater than or equal to the preset light reflectivity threshold, more light can be reflected, which can reduce the absorption and transmission of light by the light reflection layer 111, and allow more light to pass through the passivation layer 105 on the sidewall of the light emitting mesas 103 and be reflected by the light reflection layer 111, which can effectively control the optical path.

In some embodiments, the light transmittance of the light reflection layer 111 may be less than a preset light transmittance threshold.

In some embodiments, the preset light transmittance threshold may be less than or equal to 10%.

In the embodiment of the present disclosure, the light transmittance of the light reflection layer 111 is less than a preset light transmittance threshold, which can reduce light passing through the light reflection layer 111, allow more light to be reflected back within the preset light emission angle (such as within plus or minus 20°), and further improve the light emission rate and the brightness of the Micro LED display chip.

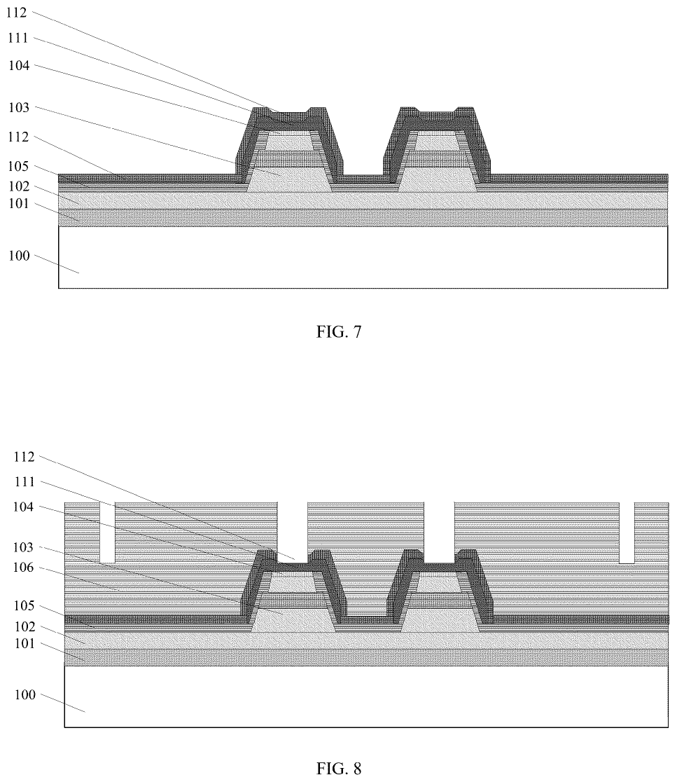

Referring to FIG. 7, a protective layer 112 is formed on the base. The protective layer 112 covers at least the light reflection layer 111.

In some embodiments, the protective layer 112 may include a stacked layer including one or more of the following: a silicon nitride layer, a titanium oxide layer and an aluminum oxide layer.

In some embodiments of the present disclosure, for the case where the protective layer 112 is a silicon nitride layer, a titanium oxide layer or an aluminum oxide layer, an appropriate thickness may be selected to achieve a better balance between process cost and device performance.

Furthermore, the protective layer 112 may satisfy one or more of the following: the protective layer 112 is a silicon nitride layer, and the thickness of the silicon nitride layer is in a range from 300 nm to 500 nm; the protective layer 112 is a titanium oxide layer, and the thickness of the titanium oxide layer is in a range from 30 nm to 80 nm; and the protective layer 112 is an aluminum oxide layer, and the thickness of the aluminum oxide layer is in a range from 30 nm to 80 nm.

Specifically, for the case where the protective layer 112 is a silicon nitride layer, the thickness of the silicon nitride layer may be, for example, 350 nm to 450 nm, such as 400 nm. By using a thicker silicon nitride layer, a better balance between process cost and device performance can be achieved.

For the case where the protective layer 112 is a titanium oxide layer, the thickness of the titanium oxide layer may be, for example, 40 nm to 70 nm, such as 50 nm. By using a thinner titanium oxide layer, a better balance between process cost and device performance can be achieved.

For the case where the protective layer 112 is an aluminum oxide layer, the thickness of the aluminum oxide layer may be, for example, 40 nm to 70 nm, such as 50 nm. By using a thinner aluminum oxide layer, a better balance between process cost and device performance can be achieved.

In some embodiments, the protective layer 112 is formed on the base, and the protective layer 112 covers at least the light reflection layer 111. The light reflection layer 111 made of more active metal materials may cause issues such as electromigration and metal material diffusion. By forming the protective layer 112 that covers at least the light reflection layer 111, the electromigration and the metal material diffusion can be effectively controlled, which can improve the lifespan and light emission efficiency of the Micro LED display chip.

Furthermore, the protective layer 112 may be formed by an Atomic Layer Deposition (ALD) process.

In some embodiments, the protective layer 112 may be formed by an ALD process, and a higher density protective layer 112 can be formed with the same material, which can further enhance the prevention effect on the electromigration and metal material diffusion.

It should be noted that the formation process of the protective layer 112 is not limited to an ALD process, and other appropriate deposition processes may also be used, such as In-situ Steam Generation (ISSG) process (also known as internal steam oxidation process), Flowable Chemical Vapor Deposition (FCVD) process, Plasma Enhanced Chemical Vapor Deposition (PECVD) process, Sub Atmosphere Chemical Vapor Deposition (SACVD) process and Low Pressure Chemical Vapor Deposition (SACVD) process.

In some embodiments, as shown in FIG. 7, the protective layer 112 may cover the light reflection layer 111 and the base.

In some embodiments, by setting the protective layer 112 to cover the light reflection layer 111 and the entire base, the protective layer 112 may be positioned on a carrier path between the P-type electrode and the N-type electrode for isolation, which can further reduce a leakage current between the P-type electrode and the N-type electrode, and further improve an electrical performance of the Micro LED display chip.

In some embodiments, the method further includes: forming a first bonding layer on the base and forming a first conductive connector in the first bonding layer; forming a driving backplane, forming a second bonding layer on the driving backplane, and forming a second conductive connector in the second bonding layer, and a position of the second conductive connector corresponds to a position of the first conductive connector; and connecting the driving backplane and the base through flip-chip bonding to electrically connect the first conductive connector and the second conductive connector.

Referring to FIG. 8, a first bonding layer 106 is formed on the base, and a through-hole is formed in the first bonding layer 106.

In some embodiments, the material of the first bonding layer 106 may include one or more of the following: silicon oxide, aluminum oxide and silicon nitride.

Specifically, a material layer of the first bonding layer 106 may be formed first, and then the first bonding layer 106 may be etched to form the through-hole. The through-hole of the first bonding layer 106 exposes the light reflection layer 111 on the top surface of each light emitting mesa 103 (which can penetrate through the protective layer 112 and expose the light reflection layer 111 when forming the protective layer 112), and exposes the P-type electrode region.

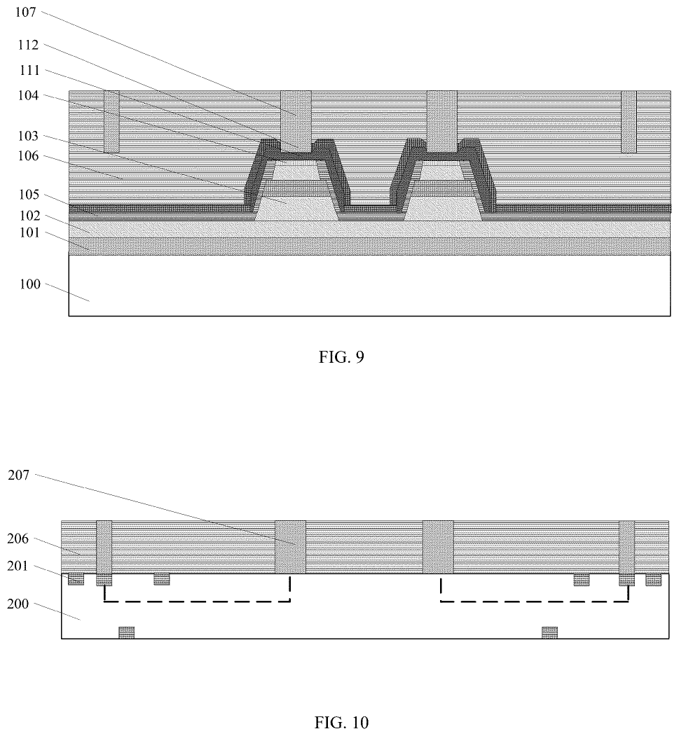

Referring to FIG. 9, a first conductive connector 107 is formed in the through-hole.

In some embodiments, the first conductive connector 107 is arranged on the light reflection layer 111 on the top surface of each light emitting mesa 103 and the P-type electrode region of the base.

In some embodiments, a material of the first conductive connector 107 may include one or more of the following: copper, tungsten, aluminum, silver, platinum and gold.

It should be understood that a depth of the first conductive connector 107 on the top surface of the light emitting mesa 103 and in the P-type electrode region can be consistent.

Referring to FIG. 10, a driving backplane 200 is formed. A second bonding layer 206 is formed on the driving backplane 200, and a second conductive connector 207 is formed in the second boding layer 206.

A position of the second conductive connector 207 is in one-to-one correspondence with a position of the first conductive connector 107.

In some embodiments, the driving backplane 200 may be, for example, a thin film transistor (TFT) board or an integrated circuit (IC) board.

The driving backplane 200 may be provided with a conductive connection structure 201, such as a conductive interconnect layer with wires and conductive plugs.

In some embodiments, the material of the second bonding layer 206 may include one or more of the following: silicon oxide, aluminum oxide and silicon nitride.

The material of the second conductive connector 207 may include one or more of the following: copper, tungsten, aluminum, silver, platinum and gold.

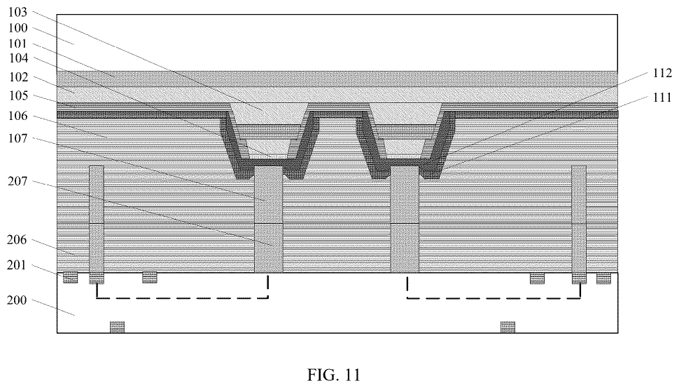

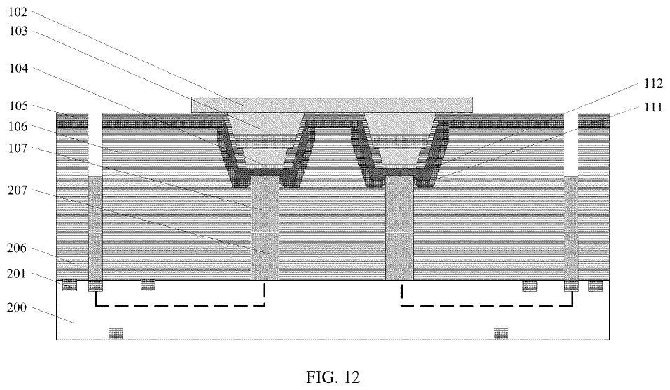

Referring to FIG. 11, the driving backplane 200 is connected with the base by flip-chip bonding, and the first conductive connector 107 is electrically connected one-to-one with the second conductive connector 207.

Specifically, the light emitting mesas 103 and the first conductive connector 107 are formed on a first surface of the base, and the substrate 100 is disposed on a second surface of the base. The first surface and the second surface of the base face each other. The second conductive connector 207 is formed on a first surface of the driving backplane 200.

An appropriate bonding process may be used to bond the first surface of the base and the first surface of the driving backplane 200 to achieve flip-chip bonding connection between the driving backplane 200 and the base.

In some embodiments, the method further includes: removing the buffer layer 101 from the second surface of the base, and exposing a back surface of each light emitting mesa 103, and etching the first electrode region to obtain a trench or a hole for forming the first electrode; and forming a second electrode on the second surface of the base and forming a first electrode electrically connected with the first conductive connector 107.

It should be noted that for the base having the substrate 100 and the buffer layer 101, the substrate 100 and the buffer layer 101 on the base may be removed from the second surface of the base to expose the back surface of each light emitting mesa 103.

It should also be noted that the first electrode may be one of the N-type electrode and the P-type electrode, and the second electrode may be the other one of the N-type electrode and the P-type electrode.

In the following description and accompanying drawings, for the sake of clarity, the first electrode is illustrated as a P-type electrode, and the second electrode is illustrated as an N-type electrode.

However, it should be noted that in other embodiments, the first electrode may also be an N-type electrode, and the second electrode may also be P-type electrode.

Referring to FIG. 12, the substrate 100 and the buffer layer 101 on the base are removed from the second surface of the base, and the back surface of each light emitting mesa 103 is exposed. The P-type electrode region is etched to obtain grooves or holes for forming P-type electrodes.

The first surface and the second surface of the base face each other, and the grooves or holes used to form the P-type electrodes correspond one-to-one with the first conductive connectors 107 in the P-type electrode region.

As mentioned above, in the process of forming each light emitting mesa 103, a portion of the thickness of the first confinement layer may be retained. Therefore, exposing the back surface of each light emitting mesa 103 may be exposing the surface of the retained first confinement layer.

In some embodiments, a portion of the epitaxial layer 102 on the passivation layer 105 may be removed while retaining the epitaxial layer 102 in the light emitting mesa region.

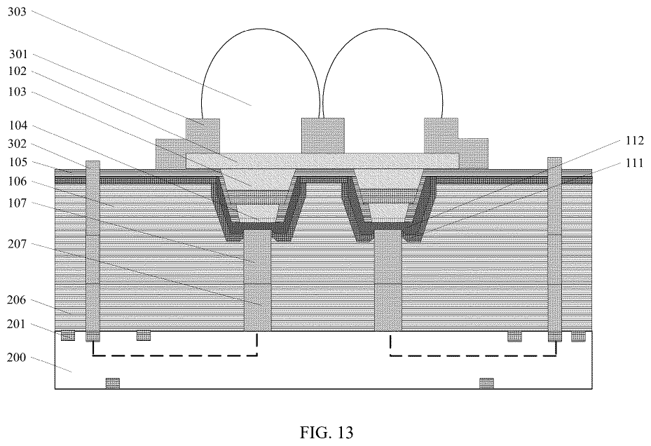

Referring to FIG. 13, an N-type electrode 301 and a P-type electrode 302 electrically connected to the first conductive connector 107 are formed on the second surface of the base.

In some embodiments, a micro lens 303 may also be formed.

Specifically, the material of the N-type electrode 301 and the P-type electrode 302 may be conventional electrode materials, such as conductive materials, suitable metal materials such as copper, tungsten, aluminum, platinum, silver and gold, and compound materials of various conductive materials.

The material of the micro lens 303 may be conventional lens materials, such as materials with a light transmittance greater than the preset light transmittance threshold.

In some embodiments, the N-type electrode 301 and the P-type electrode 302 electrically connected with the first conductive connector 107 are formed on the second surface of the base, to avoid an influence of a detachable structure on the N-type electrode 301 and the P-type electrode 302, and maintain a stability of an electrode performance of original light emitting mesa device.

Furthermore, the N-type electrode 301 may surround each light emitting mesa 103 and expose the back surface of each light emitting mesa 103.

In some embodiments, a Micro LED display chip is also provided. Referring to FIG. 13, the Micro LED display chip may include a base, a passivation layer 105 and a light reflection layer 111. The base includes a light emitting mesas 103 arranged in an array. The passivation layer 105 is arranged on a sidewall surface of each light emitting mesa 103 and a surface of the base, and exposes a top surface of each light emitting mesa 103. The light reflection layer 111 is arranged on the top surface of each light emitting mesa 103 and on a part or whole of the passivation layer 105 on the sidewall surface of each light emitting mesa 103. A light reflectivity of a material of the light reflection layer 111 is greater than or equal to a preset light reflectivity threshold.

Furthermore, the material of the light reflection layer 111 may include a stacked layer including one or more of the following: a silver layer, an aluminum layer and a gold layer.

Furthermore, the preset light reflectivity threshold may be greater than or equal to 85%.

Furthermore, a light transmittance of the light reflection layer 111 may be less than a preset light transmittance threshold.

Furthermore, the preset light transmittance threshold may be less than or equal to 10%.

Furthermore, the Micro LED display chip may further include a protective layer 112 formed on the base, and the protective layer 112 covers at least the light reflection layer 111.

Furthermore, the protective layer 112 may include a stacked layer including one or more of the following: a silicon nitride layer, a titanium oxide layer and an aluminum oxide layer.

Furthermore, the protective layer 112 may satisfy one or more of the following: the protective layer 112 is a silicon nitride layer, and the thickness of the silicon nitride layer is in a range from 300 nm to 500 nm; the protective layer 112 is a titanium oxide layer, and the thickness of the titanium oxide layer is in a range from 30 nm to 80 nm; and the protective layer 112 is an aluminum oxide layer, and the thickness of the aluminum oxide layer is in a range from 30 nm to 80 nm.

Furthermore, the protective layer 112 may cover the light reflection layer 111 and the base.

Furthermore, the base may include a substrate 100 and a stepped light emitting mesa. The substrate 100 has a light emitting mesa region, and the stepped light emitting mesa includes a first confinement layer 1031 (see FIG. 4), a quantum well layer 1032 (see FIG. 4), and a second confinement layer 1033 (see FIG. 4) formed on the substrate 100. A width of the first confinement layer 1031 is greater than a width of the second confinement layer 1033.

Furthermore, the stepped light emitting mesa is formed by etching the first confinement layer 1031, the quantum well layer 1032 and the second confinement layer 1033 using a patterned first photoresist layer 161 (see FIG. 3) and a patterned second photoresist layer 162 (see FIG. 4) respectively. A coverage size of the second photoresist layer 162 covering each light emitting mesa 103 is greater than a coverage size of the first photoresist layer 161 covering each light emitting mesa 103.

Furthermore, the second confinement layer 1033 is a sloped second confinement layer; and/or the first confinement layer 1031 is a sloped first confinement layer, and the quantum well layer 1032 is a sloped quantum well layer.

Furthermore, the sloped second confinement layer is formed by etching the second confinement layer 1033 with an inward inclined etching angle greater than 0 degrees; and/or the sloped quantum well layer and the sloped first confinement layer are formed by etching the quantum well layer 1032 and the first confinement layer 1031 with an inward inclined etching angle greater than 0 degrees. The inward inclined etching angle refers to an etching direction from diagonally above to diagonally below and from a position near a center of each light emitting mesa 103 to a position away from the center of each light emitting mesa 103.

The principle, specific implementation and beneficial effect of the Micro LED display chip can refer to the relevant description of the method for forming the Micro LED display chip mentioned above, which will not be repeated here.

It should be understood that the term “and/or” in the present disclosure is merely an association relationship describing associated objects, indicating that there can be three types of relationships, for example, A and/or B can represent: A exists only, both A and B exist, and B exists only. In addition, the character “/” in the present disclosure represents that the former and latter associated objects have an “or” relationship. As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B or C, then, unless specifically stated otherwise or infeasible, the database may include A, or B, or C, or “A and B”, or “A and C”, or “B and C”, or “A and B and C”.

The “plurality” in the embodiments of the present disclosure refers to two or more.

It should be noted that, the relational terms herein such as “first” and “second” are used only to differentiate an entity or operation from another entity or operation, and do not require or imply any actual relationship or sequence between these entities or operations. Moreover, the words “comprising”, “having”, “containing” and “including” and other similar forms are intended to be equivalent in meaning and be open ended in that an item or items following any one of these words is not meant to be an exhaustive listing of such item or items, or meant to be limited to only the listed item or items.

It should be noted that the sequence number of each step in some embodiments does not represent a limitation on the execution order of each step.

In the foregoing specification, embodiments have been described with reference to numerous specific details that may vary from implementation to implementation. Certain variations and modifications may be made to the described embodiments. Other embodiments will be apparent from consideration of the specification and practice of the present disclosure disclosed herein. The specification and examples are intended to be considered only illustrative, and the true scope and spirit of the present disclosure are indicated by the following claims. The order of steps shown in the figures is also intended to be illustrative only and is not intended to be limited to any particular order of steps. Thus, it is understood that these steps can be executed in different orders while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

Although the present disclosure has been disclosed above, the present disclosure is not limited thereto.

What is claimed is:

1. A method for forming a Micro LED display chip, comprising:
forming a base comprising a plurality of light emitting mesas arranged in an array;
forming a passivation layer on a sidewall surface of each of the plurality of light emitting mesas and a surface of the base, wherein the passivation layer exposes a top surface of each of the plurality of light emitting mesas; and
forming a light reflection layer on the top surface of each of the plurality of light emitting mesas and on a part or whole of the passivation layer on the sidewall surface of each of the plurality of light emitting mesas;
wherein a light reflectivity of a material of the light reflection layer is greater than or equal to a preset light reflectivity threshold.

2. The method according to claim 1, wherein the preset light reflectivity threshold is greater than or equal to 85%.

3. The method according to claim 1, wherein a light transmittance of the light reflection layer is less than a preset light transmittance threshold, and the preset light transmittance threshold is less than or equal to 10%.

4. The method according to claim 1, further comprising:
forming a protective layer on the base, wherein the protective layer covers at least the light reflection layer.

5. The method according to claim 4, wherein the protective layer satisfies one or more of the following:
the protective layer is a silicon nitride layer, and a thickness of the silicon nitride layer is in a range from 300 nm to 500 nm;
the protective layer is a titanium oxide layer, and a thickness of the titanium oxide layer is in a range from 30 nm to 80 nm; and
the protective layer is an aluminum oxide layer, and a thickness of the aluminum oxide layer is in a range from 30 nm to 80 nm.

6. The method according to claim 1, wherein forming the base comprises:
forming a substrate having a light emitting mesa region;
forming a first confinement layer, a quantum well layer and a second confinement layer on the substrate;
forming a patterned first photoresist layer, wherein the first photoresist layer covers each light emitting mesa in the light emitting mesa region and exposes an area between adjacent light emitting mesas;
etching the second confinement layer using the first photoresist layer and then removing the first photoresist layer;
forming a patterned second photoresist layer, wherein a coverage size of the second photoresist layer covering each light emitting mesa is greater than a coverage size of the first photoresist layer covering each light emitting mesa, wherein the second photoresist layer covers the second confinement layer of each light emitting mesa and a part of a surface of the quantum well layer surrounding the second confinement layer; and
etching the quantum well layer and the first confinement layer using the patterned second photoresist layer to form a stepped light emitting mesa.

7. The method according to claim 6, further comprising:
etching the second confinement layering with an inward inclined etching angle greater than 0 degrees to obtain a sloped second confinement layer; and/or
etching the quantum well layer and the first confinement layer with an inward inclined angle greater than 0 degrees to obtain a sloped quantum well layer and a sloped first confinement layer;
wherein the inward inclined etching angle refers to an etching direction from diagonally above to diagonally below and from a position near a center of each light emitting mesa to a position away from the center of each light emitting mesa.

8. The method according to claim 1, wherein a light transmittance of a material of the passivation layer is greater than or equal to a preset light transmittance threshold, and the preset light transmittance threshold is greater than or equal to 90%.

9. The method according to claim 1, further comprising:
forming a first bonding layer on the base and forming a first conductive connector in the first bonding layer;
forming a driving backplane, forming a second bonding layer on the driving backplane, and forming a second conductive connector in the second bonding layer, wherein a position of the second conductive connector corresponds to a position of the first conductive connector; and
connecting the driving backplane and the base through flip-chip bonding to electrically connect the first conductive connector and the second conductive connector.

10. The method according to claim 9, further comprising:
removing a substrate and a buffer layer from a second surface of the base to expose a back surface of each of the plurality of light emitting mesas, and etching a first electrode region to obtain a groove or a hole for forming a first electrode;
forming a second electrode on the second surface of the base and forming the first electrode electrically connected with the second conductive connector.

11. The method according to claim 10, wherein the second electrode surrounds each of the plurality of light emitting mesas and exposes the back surface of each of the plurality of light emitting mesas.

12. A Micro LED display chip, comprising:
a base comprising a plurality of light emitting mesas arranged in an array;
a passivation layer on a sidewall surface of each of the plurality of light emitting mesas and a surface of the base, wherein the passivation layer exposes a top surface of each of the plurality of light emitting mesas; and
a light reflection layer on the top surface of each of the plurality of light emitting mesas and on a part or whole of the passivation layer on the sidewall surface of each of the plurality of light emitting mesas;
wherein a light reflectivity of a material of the light reflection layer is greater than or equal to a preset light reflectivity threshold.

13. The Micro LED display chip according to claim 12, wherein the preset light reflectivity threshold is greater than or equal to 85%.

14. The Micro LED display chip according to claim 12, wherein a light transmittance of the light reflection layer is less than a preset light transmittance threshold, and the preset light transmittance threshold is less than or equal to 10%.

15. The Micro LED display chip according to claim 12, further comprising:
a protective layer on the base, wherein the protective layer covers at least the light reflection layer.

16. The Micro LED display chip according to claim 15, wherein the protective layer satisfies one or more of the following:
the protective layer is a silicon nitride layer, and a thickness of the silicon nitride layer is in a range from 300 nm to 500 nm;
the protective layer is a titanium oxide layer, and a thickness of the titanium oxide layer is in a range from 30 nm to 80 nm; and
the protective layer is an aluminum oxide layer, and a thickness of the aluminum oxide layer is in a range from 30 nm to 80 nm.

17. The Micro LED display chip according to claim 12, wherein the base comprises:
a substrate having a light emitting mesa region; and
a stepped light emitting mesa comprising a first confinement layer, a quantum well layer and a second confinement layer on the substrate;
wherein a width of the first confinement layer is greater than a width of the second confinement layer.

18. The Micro LED display chip according to claim 17, wherein the stepped light emitting mesa is formed by etching the first confinement layer, the quantum well layer and the second confinement layer using a patterned first photoresist layer and a patterned second photoresist layer respectively; and
wherein a coverage size of the second photoresist layer covering each light emitting mesa is greater than a coverage size of the first photoresist layer covering each light emitting mesa.

19. The Micro LED display chip according to claim 17, wherein the second confinement layer is a sloped second confinement layer; and/or
the first confinement layer is a sloped first confinement layer, and the quantum well layer is a sloped quantum well layer.

20. The Micro LED display chip according to claim 19, wherein the sloped second confinement layer is formed by etching the second confinement layer with an inward inclined etching angle greater than 0 degrees; and/or
the sloped quantum well layer and the sloped first confinement layer are formed by etching the quantum well layer and the first confinement layer with an inward inclined etching angle greater than 0 degrees;
wherein the inward inclined etching angle refers to an etching direction from diagonally above to diagonally below and from a position near a center of each light emitting mesa to a position away from the center of each light emitting mesa.
